(19) United States
(12) Patent Application Publication
(10) Pub. No.: US 2021/0311299 A1
(43) Pub. Date: Oct. 7, 2021

(54) DISPLAY DEVICE AND OPERATING METHOD

(71) Applicant: OSRAM OLED GMBH, Regensburg (DE)

(72) Inventors: Daniel RICHTER, Bad Abbach (DE); Luca HAIBERGER, Regensburg (DE)

(21) Appl. No.: 17/263,026

(22) PCT Filed: Jul. 18, 2019
(86) PCT No.: PCT/EP2019/069405

§ 371 Date: Jan. 25, 2021

(30) Foreign Application Priority Data
Aug. 3, 2018 (DE) 10 2018 118 931.1

(51) Int. Cl. G02B 26/08; G02B 26/00; G02B 30/30; G02B 27/28; G02B 30/25

(52) U.S. Cl. CPC G02B 26/0833; G02B 26/007; H01L 25/0753; G02B 27/288; G02B 30/25; G02B 30/30

(57) ABSTRACT

In an embodiment, the display device comprises a light emitting semiconductor chip having a light exit side and a mask layer disposed downstream of the semiconductor chip and comprising a plurality of openings. In the openings, the semiconductor chip is free from the mask layer. A movable cover is made of an opaque material and is configured with a plurality of penetrations for adjusting a radiation characteristic of the semiconductor chip. The penetrations are at least temporarily associated with the openings. A drive unit is provided for moving the cover in the direction parallel to the light exit side.

A display device is specified. In addition, an operating method is specified.

An object to be solved is to specify a display device in which the optical properties of an emitted radiation are efficiently adjustable.

This object is solved, inter alia, by a display device having the features of claim 1. Preferred further developments are the subject of the remaining claims.

In particular, a display device is specified in which a MEMS element is mounted on an LED chip. The MEMS element moves in a lateral direction. The direction, polarization and/or color of the emitted radiation is adjusted via openings in the MEMS element, which are located at different positions above the LED chip as a function of time. MEMS stands for micro-electro-mechanical system.

According to at least one embodiment, the display device is a display or a part of a display. The display device is preferably configured to display color images and/or movies. For this purpose, the display device comprises a large number of pixels, also referred to as pixels.

According to at least one embodiment, the display device comprises one or, preferably, a plurality of semiconductor chips. The at least one semiconductor chip is configured to emit light. The term light may include here and hereinafter near-ultraviolet radiation, visible light, and near-infrared radiation. Preferably, the semiconductor chip emits visible light, such as blue light. For example, a wavelength of maximum intensity of radiation generated by the semiconductor chip in operation is at least 400 nm or 420 nm or 430 nm and/or at most 480 nm or 460 nm.

According to at least one embodiment, the semiconductor chip comprises a light exit side. At the light exit side, a predominant portion or all of the radiation generated in the semiconductor chip is coupled out of the semiconductor chip and emitted. Preferably, the light exit side is flat or approximately flat in shape. The light exit side is a main side of the semiconductor chip.

According to at least one embodiment, the display device comprises one or a plurality of mask layers. The at least one mask layer is arranged downstream of the semiconductor chip. In particular, this means that the light generated in the semiconductor chip can only leave the display device through the mask layer. Preferably, the mask layer is made of a reflective material that is opaque to visible light, such as a metal.

According to at least one embodiment, the mask layer comprises a plurality of openings. The openings are located on the light exit side, as viewed in plan view. In the openings, the semiconductor chip is free of a material of the mask layer.

According to at least one embodiment, the display device comprises one or a plurality of movable covers. The at least one movable cover is made of an opaque material. For example, the cover is a metal foil or a metal plate. Alternatively, the cover is a semiconductor material.

According to at least one embodiment, the cover comprises a plurality of penetrations. Preferably, the penetrations extend through the entire cover such that, as viewed in plan view, no material of the cover is located in the penetrations, in particular no opaque material.

According to at least one embodiment, the penetrations are configured for adjusting a radiation characteristic of the semiconductor chip. This is achieved by the penetrations being temporarily or permanently associated with the openings. For example, the penetrations cover the openings to different extents at different times, or certain penetrations cover openings previously associated with other penetrations.

Alternatively, it is possible that the drive unit is not integrated in the display device, but forms an external component. In this case, the display device preferably comprises at least one connector or plug-in facility for the drive unit.

According to at least one embodiment, the display device comprises at least one drive unit for moving the cover. The cover is preferably moved in a direction parallel or approximately parallel to the light exit side. In particular, the cover is moved parallel to the light exit side with a tolerance of at most 10° or 5° or 1°.

In at least one embodiment, the display device comprises at least one light emitting semiconductor chip having a light exit side and at least one mask layer disposed downstream of the semiconductor chip and comprising a plurality of openings. In the openings, the semiconductor chip is free of the mask layer. At least one movable cover is made of an opaque material and is configured with a plurality of penetrations for adjusting a radiation pattern of the semiconductor chip. The penetrations are at least temporarily associated with the openings. At least one drive unit is provided for moving the cover in a direction parallel to the light exit side.

The emission of LED chips, such as the semiconductor chip described here, is typically Lambertian and accordingly comprises a maximum intensity in the 0° direction, i.e. in the direction perpendicular to the light exit side. By means of passive optical elements, the radiation characteristic can be shaped so that, for example, an intensity maximum is not emitted along the 0° direction. However, in particular the direction along which the intensity maximum is emitted is usually not switchable or only switchable to a very limited extent.

In the display device described here, the direction of radiation in particular is adjustable by means of the MEMS element, i.e. by means of the cover. In other words, the cover can form an aperture that covers the semiconductor chip and the openings in the mask to varying degrees. This achieves directional selectivity, depending on the respective position of the cover relative to the semiconductor chip.

Thus, if the cover is moved relative to the mask layer, the radiation characteristic can be changed continuously or discretely. Accordingly, the directional maximum of the radiation characteristic can be varied over a certain angular range. The degree of the possible tuning angle is essentially adjustable by the thickness of the cover and the mask layer. The same applies to a half-value angle for the radiation characteristic.

In addition to the continuous adjustability of the solid angle for the intensity maximum, short switching times in the range of 100 μs or less can also be realized by using MEMS elements for the cover.

According to at least one embodiment, the mask layer is immobile and stationary relative to the semiconductor chip. For example, the mask layer is fixed directly to the light exit side. In the intended use of the display device, the mask layer does not change its position relative to the semiconductor chip. That is, the openings in the mask layer are also stationary relative to the semiconductor chip.

According to at least one embodiment, the mask layer comprises optical properties that remain constant as intended. That is, the mask layer is an optically passive element that is not switched or selectively changed in its optical properties. This does not preclude the properties of the mask layer from changing over the life of the display device due to aging effects. However, in the intended operation of the display device, no or no significant change in the optical properties of the mask layer occurs on short time scales. Short time scales means, for example, in the range of hours or days. In particular, the only movable and/or switchable optical element of the display device is given by the cover.

According to at least one embodiment, a thickness of the mask layer is at least half as large or at least as large or at least twice as large as an average diameter of the openings. That is, the mask layer comprises a comparatively large thickness.

According to at least one embodiment, a thickness of the cover is at least quarter as large or at least half as large or at least as large or at least twice as large as a mean diameter of the penetrations. Thus, the cover also preferably comprises a comparatively large thickness.

According to at least one embodiment, the mean diameter of the openings and/or the penetrations is at least 2 μm or 5 μm or 10 μm. Alternatively or additionally, this average diameter is at most 100 μm or 50 μm or 20 μm.

According to at least one embodiment, the thickness of the mask layer and/or the thickness of the cover is at least 2 μm or 5 μm or 10 μm. Alternatively or additionally, this thickness is at most 100 μm or 50 μm or 20 μm. In particular, this thickness is larger by at least a factor of 2 or 5 or 10 than a wavelength of maximum intensity of the radiation generated by the semiconductor chip in operation.

According to at least one embodiment, the semiconductor chip is subdivided into a plurality of pixels that are drivable electrically independently of each other. In other words, the semiconductor chip is a pixelated chip. The various electrically independently drivable regions of the semiconductor chip preferably generate radiation of the same color during operation within manufacturing tolerances. It is possible that the individually drivable pixels or groups of pixels are uniquely or in a one-to-one correspondence associated with the openings in the mask layer. In particular, each of the openings is associated with exactly one of the pixels. It is possible that the pixels and the openings are arranged to be congruent or substantially congruent, as seen in plan view of the light exit side.

According to at least one embodiment, the semiconductor chip is electrically a single unit such that, in operation of the semiconductor chip, the light exit side is configured to emit light over its entire surface or substantially its entire surface simultaneously. In other words, the semiconductor chip is then not a pixelated chip, but is electrically operable only as a single component. The semiconductor chip per se is thus not electrically and optically divided into subcomponents, in particular not into individually adjustable subcomponents for independent radiation generation.

According to at least one embodiment, the cover is downstream of the mask layer. In particular, this means that the light of the semiconductor chip that has passed through the mask layer is emitted from the display device only through the cover.

According to at least one embodiment, the cover is located between the light exit side and the mask layer. Thus, the light generated in the semiconductor chip first reaches the cover and only then reaches the mask layer. Such arranging is especially possible if the semiconductor chip is not pixelated.

According to at least one embodiment, the area of the mask layer provided with the openings, the area of the cover provided with the penetrations and the light exit side are of the same size or approximately the same size when viewed in plan view. Approximately equal in size means, in particular, with a tolerance of at most the mobility of the cover in the direction parallel to the light exit side. Thus, through the mask layer and the cover, there is essentially no or no significant increase in an emitting area, relative to the size of the light exit side.

According to at least one embodiment, the display device comprises a further mask layer. The cover is preferably located between the mask layer and the further mask layer. Thereby, the further mask layer may be closer to the light exit side than the mask layer or vice versa.

According to at least one embodiment, the mask layer and the further mask layer are structurally identical. This applies in particular with respect to an arranging and a size of the openings. In particular, the openings in the mask layer and in the further mask layer lie congruently one above the other within the manufacturing tolerances. It is possible that the mask layer and the further mask layer are identical in construction except for their thicknesses. In particular, the mask layer and the further mask layer are constructed of the same material or materials.

According to at least one embodiment, the cover is configured as a polarizing filter. For this purpose, the cover preferably comprises first regions and second regions. The first regions are more transparent to light of a different polarization than the second regions. For example, the first regions are transmissive for s-polarized light and the second regions are transmissive for p-polarized light.

In operation of the cover, the first regions and the second regions are preferably alternately located over their respective associated openings. Thus, it is achievable via the cover that alternately differently polarized light is emitted. With the aid of polarization-dependent transmissive spectacles worn by a viewer, three-dimensional images can thus be displayed using the display device.

According to at least one embodiment, the cover is designed as a directional filter. For this purpose, light is emitted from the display device and/or from the semiconductor chip in question in different directions during operation depending on the position of the cover relative to the mask layer. The direction along which the radiation is emitted is preferably tuned rapidly. Thus, the display device can preferably be used to display autostereoscopic three-dimensional images and movies.

According to at least one embodiment, the display device includes a pixel mask. The pixel mask includes a plurality of pixel openings. The pixel openings form pixels of the display device, wherein a plurality of pixel openings emitting different colors may be combined to form a pixel emitting adjustable colors. If such a pixel mask is present, the display device preferably comprises a plurality of the semiconductor chips. The pixel mask is preferably arranged downstream of the cover as well as the mask layer. In particular, the pixel mask is spaced apart from the cover and the mask layer.

According to at least one embodiment, a plurality of the pixel openings are uniquely associated with each of the semiconductor chips. The cover can thus be designed as a pixel multiplexer, so that in operation, depending on the position of the cover relative to the mask layer, only one of the assigned pixel openings of the pixel mask is illuminated in each case by the semiconductor chip concerned.

Especially in the case of video walls, also known as video walls, in which the individual pixels are formed by semiconductor chips, the LED chips represent a considerable cost factor. With the coverage described here, one and the same semiconductor chip can be used for several of the pixels. As a result, lower cost display devices can be created. Since in video walls the individual semiconductor chips are usually operated by pulse width modulation and are used for light generation only for a relatively small time fraction per pixel, several of the pixel openings can be served in time succession by the semiconductor chip by means of the cover without the need for a reduction of the radiation brightness and/or the time resolution.

According to at least one embodiment, the display device comprises one or more phosphors. The at least one phosphor may be attached to the cover and may be movably mounted therewith. Alternatively, the at least one phosphor is located on another component of the display device and is fixedly mounted relative to the mask layer and the semiconductor chip. Preferably, there is a phosphor for generating red light and a phosphor for generating green light. If the at least one semiconductor chip does not emit blue light but, for example, emits near-ultraviolet radiation, a phosphor for generating blue light is preferably also present.

According to at least one embodiment, the cover is designed as a color adjustment unit. That is, in operation, light of a specific color is emitted depending on the position of the cover. This is achieved in particular by the fact that, due to the respective position of the cover, the light generated by the semiconductor chip in each case only reaches a specific phosphor or, in the case of blue light, is emitted directly without contact with the phosphor.

According to at least one embodiment, the display device comprises at least one index matching layer. The one or more index matching layers are preferably located between the mask layer and the light exit side. A refractive index of the index matching layer for the light generated in the semiconductor chip in operation decreases in a direction away from the light exit side. The decrease in refractive index may be gradual or continuous. Such an index matching layer can increase a coupling-out efficiency.

According to at least one embodiment, the openings and/or the penetrations are arranged two-dimensionally as seen in plan view of the light exit side. For example, the openings and/or the penetrations are located in a regular square or rectangular or even hexagonal grid when viewed in plan view. In the case of a two-dimensional arrangement of the openings and/or the penetrations, the drive unit is preferably configured to move the cover in two dimensions, for example independently or correlated along two orthogonal directions. Thus, a tuning of the optical properties of the emitted radiation can be adjusted two-dimensionally and the display device can comprise two-dimensionally arranged pixels.

According to at least one embodiment, the openings and/or the penetrations are slit-shaped in plan view onto the light exit side. In particular, the openings and/or the penetrations are arranged side by side along only one direction. The drive unit is preferably configured to move the cover only one-dimensionally, in particular in a direction perpendicular to a longitudinal extent of the slits. In this way, an efficient and simple tuning of the radiation direction of maximum intensity or of the polarization of the radiated light can be achieved. This is especially true if three-dimensional images are to be displayed by the display device only to a seated or standing viewer whose eyes are substantially in a line parallel to the tuning and shifting of the cover.

The shifting of the cover may also be only one-dimensional, although the pixels and/or the openings are arranged two-dimensionally. In this case, the bridging may be slot-shaped in one dimension or arranged in a rectangular or hexagonal grid in two dimensions.

According to at least one embodiment, the drive unit, optionally together with the cover, comprises a piezo actuator, an electrostatic slider, a micro spring, a magnetic slider and/or a micro pendulum. Such components can be driven at high frequencies and thus quickly, so that the cover can be guided over the openings in the mask layer at a high frequency.

In this context, it is possible for the cover to be controlled discretely and comprise only comparatively few defined positions, so that control is performed digitally with exactly two defined positions, for example. Alternatively, the cover can be moved continuously without having predetermined fixed positions. If discrete positions are available for the cover, the semiconductor chip is preferably electrically controlled synchronously with the drive unit.

According to at least one embodiment, the drive unit is configured to move the cover in the direction parallel to the light exit side by at least 2 μm or 5 μm or 10 μm and/or by at most 20 μm. This can apply to a one-dimensional as well as to a two-dimensional movement. In the case of a two-dimensional movement, this preferably applies to each direction of movement.

In the 2007 publication N. Hagood et al, A Direct-View MEMS Display for Mobile Applications, in SID 07 DIGEST, pages 1278 to 1281, ISSN 007-0966X-07-3802-1278, fast switching MEMS units for displays are specified. The disclosure content of this publication for the MEMS units, that is, for the cover and/or for the drive unit, is incorporated by reference.

In addition, an operating method for such a display device is specified. Features of the display device are therefore also disclosed for the operating method, and vice versa.

In at least one embodiment, the cover is temporarily or permanently moved by the drive unit in a direction parallel to the light exit side so that, depending on the position of the cover relative to the mask layer, light is emitted by the display device at different locations and/or in different directions and/or with optical properties that differ from one another. In particular, optical properties include the color of the light, the polarization of the light, and/or the intensity of the light.

In the following, a display device described herein and an operating method described herein are explained in more detail with reference to the drawings by means of exemplary embodiments. Identical reference signs thereby specify identical elements in the individual figures. However, no references are shown to scale; rather, individual elements may be shown exaggeratedly large for better understanding.

In the Figures:

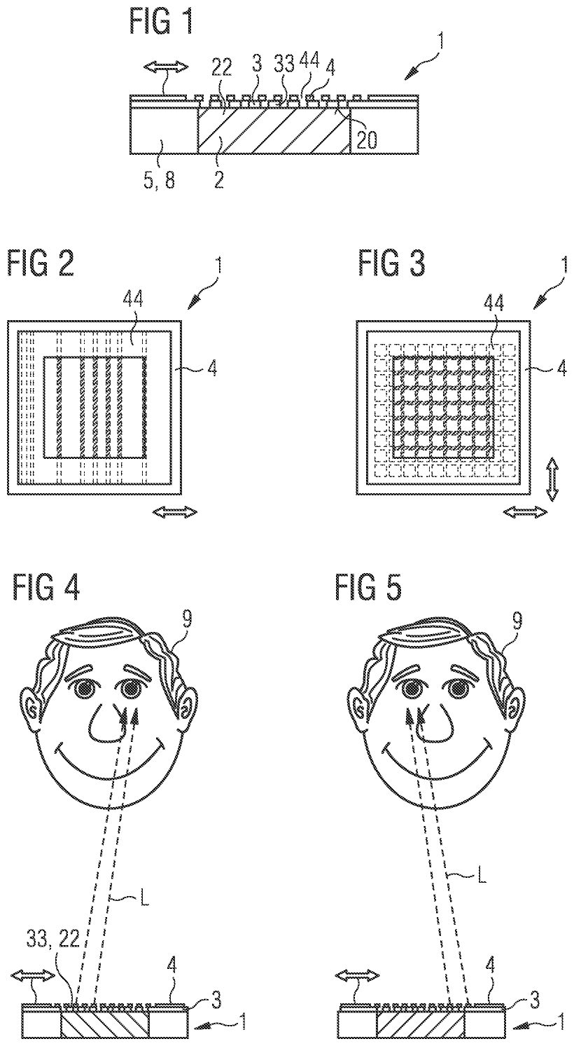

FIG. 1 shows a schematic sectional view of an exemplary embodiment of a display device described herein,

FIGS. 2 and 3 show schematic top views of exemplary embodiments of display devices described herein,

FIGS. 4 and 5 show schematic representations of steps of an operating procedure for a display device described herein,

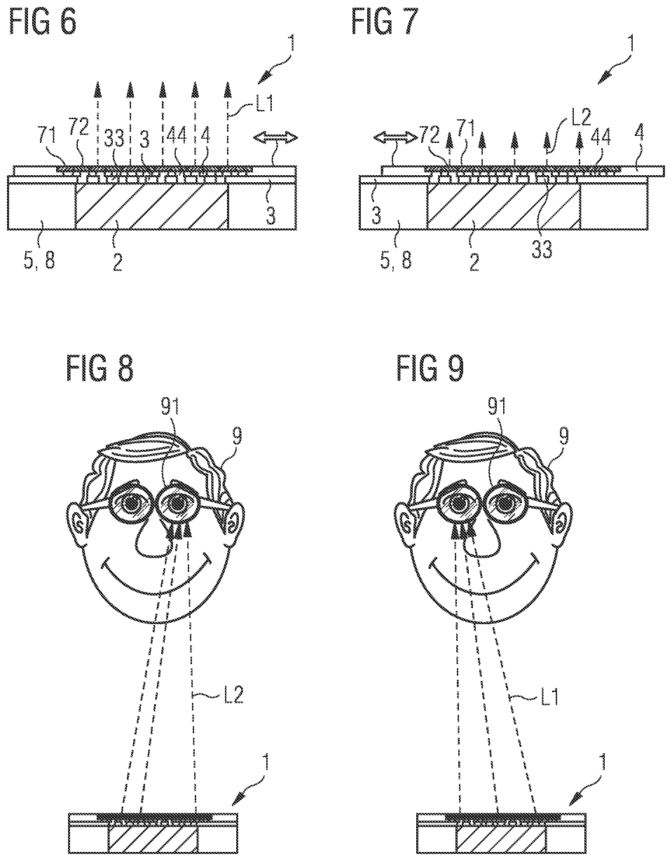

FIGS. 6 and 7 show schematic sectional views of exemplary embodiments of display devices described herein,

FIGS. 8 and 9 show schematic sectional views of an operating method for a display device described herein,

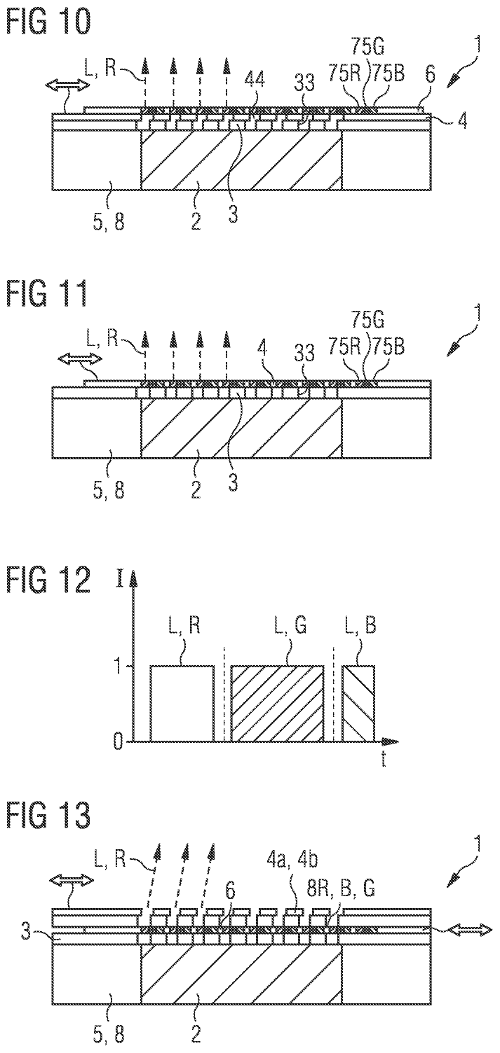

FIGS. 10 and 11 show schematic sectional views of exemplary embodiments of display devices described herein,

FIG. 12 shows a schematic illustration of a time dependence of a drive of a semiconductor chip in a display device described herein,

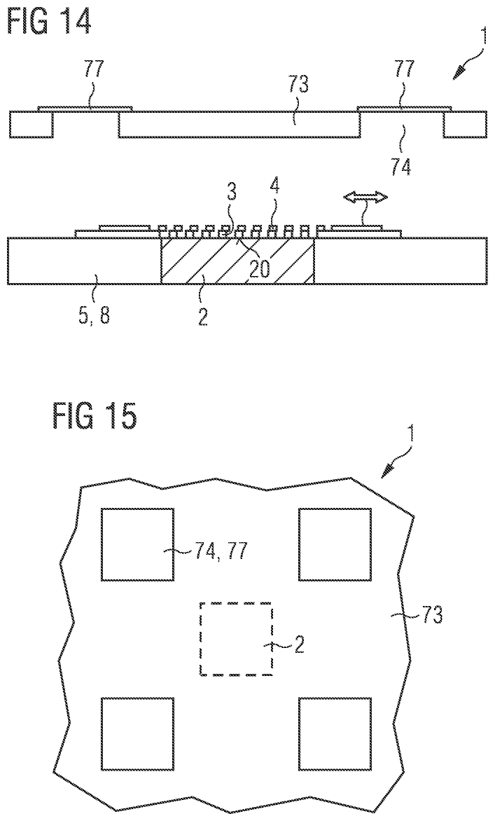

FIGS. 13 and 14 show schematic sectional views of exemplary embodiments of display devices described herein,

FIG. 15 shows a schematic top view of an exemplary embodiment of a display device described herein, and

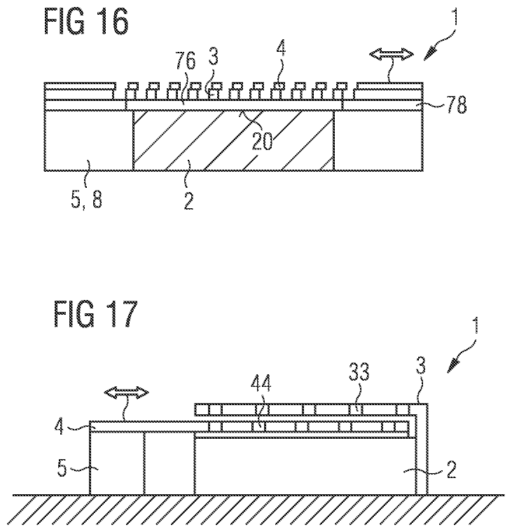

FIGS. 16 and 17 show schematic sectional views of exemplary embodiments of display devices described herein.

FIG. 1 illustrates an exemplary embodiment of a display device 1. The display device 1 comprises a light-emitting semiconductor chip 2, for example a blue light-emitting LED chip. The semiconductor chip 2 may be subdivided into a plurality of pixels 22. The pixels 22 are preferably electrically independently controllable. The semiconductor chip 2 comprises a light exit side 20, which may extend collectively over all pixels 22.

The semiconductor chip 2 is located, for example, in a carrier potting 8. Via the carrier potting 8, a base surface of the display device 1 can be enlarged relative to the bare semiconductor chip 2. It is possible that further electrical components of the display device 1, such as drive chips or memory units, are accommodated in the carrier potting 8. Furthermore, undrawn electrical contact pads may be provided on the carrier potting 8 and/or on the semiconductor chip 2.

Furthermore, the display device 1 comprises a mask layer 3. The mask layer 3 is preferably reflective. For example, the mask layer 3 is made of a metal or also of a silicone filled with reflective particles, such as titanium dioxide particles.

There are many openings 33 in the mask layer 3. In the openings 33, the light exit side 20 is exposed. An average width of the openings 33, when viewed in cross section, is approximately as large as a thickness of the mask layer 3. The mask layer 3, and thus the openings 33, are stationary relative to the semiconductor chip 2.

A cover 4 is provided on a side of the mask layer 3 facing away from the semiconductor chip 2. The cover 4 is made of an opaque material. The cover 4 comprises many penetrations 44. There is a one-to-one correspondence between the openings 33 and the penetrations 44; this applies in particular to the penetrations 44 above the light exit side 20, but need not necessarily apply to penetrations 44 adjacent to the light exit side 20.

The cover 4 is movable in the direction parallel to the light exit side 20 relative to the semiconductor chip 2 and thus relative to the mask layer 3. This is symbolized by a double arrow. The movement can be fast, for example with a frequency of at least 2 kHz or 20 kHz.

The movement of the cover 4 is determined by a drive unit 5. The drive unit 5 may be integrated in the carrier potting 8. A possible displacement path or displacement width of the cover 4 in the direction parallel to the light exit side 20 is approximately at a width of the openings 3 and the penetrations 44. Thus, the openings 3 can be completely covered by the cover 4 as well as completely or almost completely opened. A width of the cover 4 between the individual penetrations 44 is preferably at least as large as a width of the openings 3. The same preferably applies to all other embodiments.

FIGS. 2 and 3 illustrate top views of the cover 4. According to FIG. 2, the penetrations 44 are slot-shaped. Thus, the cover 4 is structured along only one direction, i.e. in FIG. 2 along a left-right direction. In contrast, the cover 4 in FIG. 3 is structured in two dimensions, so that the penetrations 44 are arranged in particular in a square grid.

In FIG. 3, it is possible that a movement of the cover 4 takes place along two orthogonal directions. Alternatively, also according to FIG. 3, only a one-dimensional movement of the cover 4 can take place.

The two possibilities of FIGS. 2 and 3, i.e. a one-dimensional or a two-dimensional arranging of the of the penetrations 44 and optionally of the openings 33, may be correspondingly present in all other exemplary embodiments.

An operating method of the display device 1 of, for example, FIG. 1 is illustrated in FIGS. 4 and 5. The display device 1 is used to display autostereoscopic three-dimensional images. Thus, light L is emitted from the display device 1 towards a viewer 9, wherein the eyes of the viewer 9 perceive different image information, so that the three-dimensional impression is created.

For this purpose, the cover 4 covers the openings 33 of the mask layer 3 differently in each case. This different covering results in directional selectivity. This means that, depending on the position of the cover 4, light is emitted in a specific solid angle range and a specific direction of maximum intensity can be set. This is made possible in particular by the comparatively large thickness of the mask layer 3 and/or the cover 4.

A control of the individual pixels 22 preferably takes place synchronously with the respective position of the cover 4. Thus, depending on the viewing distance of the viewer and the position of the MEMS element, i.e. the cover 4, different image contents can be transported to the two eyes of the viewer 9.

FIGS. 6 and 7 illustrate another exemplary embodiment of the display device 1. The semiconductor chip 2, the mask layer 3, the drive unit 5 and the optional carrier potting 8 are designed, for example, as explained in connection with FIG. 1.

On the one hand, the cover 4 comprises the penetrations 44 located on a side facing the semiconductor chip 2. On the other hand, first regions 71 and second regions 72 are located on a side of the apertures 44 facing away from the semiconductor chip 2. The two regions 71, 72 are transparent to light of different polarizations.

Depending on the position of the cover 4 relative to the semiconductor chip 2, vertically polarized light L1, for example, is thus emitted through the first regions 71, see FIG. 6. If the cover 4 moves further, parallel polarized light L2, for example, is emitted through the second regions 72, see FIG. 7.

If the viewer 9 wears spectacles 91 with polarization-dependent transmissive lenses, for example, one eye receives the radiation L2 and the other eye receives the radiation L1. Thus, polarization-dependent perception of the light L1, L2 is possible from the display device 1 together with the spectacles 91, and three-dimensional images can be displayed.

The cover of the display device 1, as explained in connection with FIGS. 6 to 9, can be structured one-dimensionally or two-dimensionally when viewed in plan view, compare FIGS. 2 and 3.

In the exemplary embodiment of FIG. 10, another mask layer 6 is present. The movable cover 4 is located between the two stationary mask layers 3, 6. For the individual openings 33, the further mask layer 6 comprises respective regions with a phosphor 75R for generating red light, a phosphor 75G for generating green light and a phosphor 75B for generating blue light. If the semiconductor chip 2 already emits blue light, the phosphor 75B may be replaced by a translucent region having no wavelength conversion characteristics.

Depending on the position of the cover 4, light from the semiconductor chip 2 reaches only one phosphor region at a time to generate light of only a particular color. Thus, depending on the position of the cover 4, for example, only red light, only green light or only blue light is emitted. With a semiconductor chip 2, in particular a pixelated semiconductor chip, which emits light of only a single color, it is thus possible to generate images of different colors.

The division into red, green and blue thus takes place at the level of the further mask layer 6 and not at the level of the semiconductor chip 2. It is thus sufficient for the semiconductor chip 2 to comprise only one third of the number of pixels as would otherwise be necessary without the movable cover 4. So, more simply constructed semiconductor chips 2 with fewer pixels can be used or, for a given number of pixels of the semiconductor chip 2, a correspondingly higher image resolution of the display device 1 can be realized.

In FIG. 11 it is shown that the phosphors 75R, 75G and optionally 75B are already integrated in the cover 4. That is, the phosphors fill the penetrations 44. Accordingly, the openings 33 in the mask layer 3 are relatively small, so that only one of the phosphors 75R, 75G and optionally 75B is irradiated at a time.

An example of driving the display devices 1 of FIGS. 10 and 11 is illustrated in FIG. 12. The semiconductor chip 2 or pixels of the semiconductor chip 2 are driven in particular by pulse width modulation. If the relevant phosphor for generating light of the desired color is located above the corresponding pixel of the semiconductor chip, the latter is switched on and light of the desired intensity and color is emitted. If the cover 4 moves, the semiconductor chip is preferably switched off. The time range in which the cover 4 moves is symbolized by vertical dash lines in FIG. 12.

Thus, the red, green and blue light can be sequentially obtained with the respective pixel of the semiconductor chip 2, resulting in total in a pixel with an adjustable emission color.

In the exemplary embodiment of FIG. 13, the covers of FIGS. 1 and 11 are combined. The cover 4a, which is located closer to the semiconductor chip 2, is configured for adjustable generation of red, green and blue light, as explained in particular in connection with FIGS. 11 and 12.

Via the cover 4b, which is located further away from the semiconductor chip 2, the radiation direction of the light is determined, depending on the position of the cover 4 relative to the openings in the mask layers 3, 6. Thus, the cover 4b operates as explained in FIG. 1.

In FIGS. 14 and 15, it is shown that due to the directivity of the cover 4, it is possible to address a discrete number of pixels using a single LED chip. For this purpose, a semiconductor chip 2, a mask layer 3 and a cover 4 are used, in particular as shown in connection with FIG. 1. However, the semiconductor chip 2 need not be pixelated, but can be unpixelated and thus comprise a continuous, unstructured light exit side 20.

A pixel mask 73 is located above and spaced from the cover 4. The pixel mask 73 comprises a plurality of pixel openings 74. The pixel openings 74 are optionally covered by a diffuser 77 for light diffusion. The semiconductor chip 2 is preferably not visible through the pixel mask 73.

From the cover 4, the emitted light is directed in each case in such a way that it strikes the, for example, four associated pixel openings 74 one after the other in time and is emitted through them. This corresponds to a time-multiplexed illumination of the pixel openings 74. Thus, a number of semiconductor chips 2 required to form the pixel openings 74 and thus the pixels of the display device 1 can be reduced by a factor of 4.

Also in FIGS. 14 and 15, it is possible to use the configuration in particular of FIG. 13 and/or FIG. 11, so that moreover the emitted color is adjustable. Furthermore, more than four pixel openings 74 can be controlled, for example nine or 16 pixel openings 74.

In the exemplary embodiment of FIG. 16, the display device 1 additionally comprises an index matching layer 76. The index matching layer 76 is located between the mask layer 3 and the light exit side 20. In particular, the index matching layer 76 is located directly at the light exit side 20. In the index matching layer 76, a refractive index for the generated light decreases in the direction away from the light exit side 20. Thus, a light coupling-out efficiency can be increased.

Optionally, a reflector 78, for example made of a white material such as a silicone, to which reflective particles of, for example, titanium dioxide are added, is located laterally adjacent to the index matching layer 76.

Such an index matching layer 76 and/or such a reflector 78 can also be present in all other exemplary embodiments.

FIG. 17 illustrates that the drive unit 5 may be mounted as a separate component adjacent to the semiconductor chip 2. Thus, the carrier potting 8 may be omitted.

Furthermore, FIG. 17 illustrates that the cover 4 can also be located between the semiconductor chip 2 and the mask layer 3. The mask layer 3 is preferably firmly connected to the semiconductor chip 2 and/or to a carrier such as a printed circuit board via corresponding supports, so that a defined relationship is achieved between the openings 33 and the penetrations 44.

Unless otherwise indicated, the components shown in the figures preferably follow each other directly in the sequence indicated. Layers not touching each other in the figures are preferably spaced apart. Insofar as lines are drawn parallel to each other, the corresponding surfaces are preferably also aligned parallel to each other. Also, unless otherwise indicated, the relative positions of the drawn components to each other are correctly reproduced in the figures.

This patent application claims priority to German patent application 10 2018 118 931.1, the disclosure content of which is hereby incorporated by reference.

The invention described herein is not limited by the description based on the exemplary embodiments. Rather, the invention encompasses any new feature as well as any combination of features, which in particular includes any combination of features in the patent claims, even if that feature or combination itself is not explicitly specified in the patent claims or exemplary embodiments.

### LIST OF REFERENCE SIGNS

1 display device
2 light emitting semiconductor chip
20 light exit side
22 pixel
3 mask layer
33 opening
4 cover
44 penetration
5 drive unit
6 further mask layer
71 first polarizer area of the cover
72 second polarizer area of the cover
73 pixel mask
74 pixel opening
75 phosphor
76 index matching layer
77 diffuser
78 reflector
8 carrier potting
9 viewer
91 spectacles with polarization-dependent transmissive sides
I current
L light
t time

1. A display device with
at least one light-emitting semiconductor chip having a light exit side,
at least one mask layer which is arranged downstream of the semiconductor chip and which comprises a plurality of openings in which the semiconductor chip is free of the mask layer,
at least one movable cover made of an opaque material and having a plurality of penetrations for adjusting a radiation characteristic of the semiconductor chip so that the penetrations are at least temporarily associated with the openings, and
at least one drive unit for moving the cover in a direction parallel to the light exit side.

2. The display device according to claim 1,
wherein
the mask layer is of an opaque reflective material,
the mask layer is immobile and stationary relative to the semiconductor chip and comprises constant optical properties, and
a thickness of the mask layer is at least as large as an average diameter of the openings, and
a thickness of the cover is at least half as large as a mean diameter of the penetrations.

3. The display device according to claim 1,
wherein the semiconductor chip is subdivided into a plurality of electrically independently drivable pixels.

4. The display device according to claim 1,
wherein the semiconductor chip electrically constitutes a single unit, so that in operation of the semiconductor chip the light exit side is configured to emit light over the entire surface.

5. The display device according to claim 1,
wherein the cover is arranged downstream of the mask layer.

6. The display device according to claim 1,
wherein the cover is located between the light exit side and the mask layer.

7. The display device according to claim 1,
further comprising a further mask layer,
wherein the cover is located between the mask layer and the further mask layer, and
wherein the mask layer and the further mask layer are identical in construction except for their thicknesses.

8. The display device according to claim 1,
wherein the cover is configured as a polarizing filter and comprises first regions and second regions,
wherein the first regions are transmissive to light of a different polarization than the second regions.

9. The display device according to claim 1,
wherein the cover is configured as a directional filter so that, in operation, light is emitted from the display device in different directions depending on the position of the cover relative to the mask layer.

10. The display device according to claim 1,
comprising a plurality of said semiconductor chips and further comprising a pixel mask having a plurality of pixel openings,
wherein the pixel mask is subsequent to the mask layer and the cover,
wherein a plurality of said pixel openings are uniquely associated with each of said semiconductor chips,
wherein the cover is designed as a pixel multiplexer, so that in operation, depending on the position of the cover relative to the mask layer, only one of the associated pixel openings is illuminated by each semiconductor chip.

11. The display device according to claim 1,
comprising at least one phosphor attached to the cover, wherein the cover is configured as a color setting unit such that, in operation, light of a specific color is emitted depending on the position of the cover.

12. The display device according to claim 1,
further comprising an index matching layer,
wherein the index matching layer is disposed between the mask layer and the light exit side, and
wherein a refractive index of the index matching layer for light generated in the semiconductor chip in operation decreases in a direction away from the light exit side.

13. The display device according to claim 1,
wherein the openings and the penetrations are arranged two-dimensionally as seen in plan view of the light exit side, and
wherein the drive unit is configured to move the cover two-dimensionally.

14. The display device according to claim 1,
wherein the openings and the penetrations, as seen in plan view of the light exit side, are shaped like slits and are juxtaposed along only one direction, and
wherein the drive unit is configured to move the cover one-dimensionally.

14. The display device according to claim 1,
wherein the openings and the penetrations, as seen in plan view of the light exit side, are shaped like slits and are juxtaposed along only one direction, and
wherein the drive unit is configured to move the cover one-dimensionally.

15. The display device according to claim 1,
wherein the drive unit comprises a piezo actuator, an electrostatic slider, a micro spring, a magnetic slider and/or a micro pendulum,
wherein the drive unit is configured to move the cover in the direction parallel to the light exit side by at least 5 μm.

16. An operating method for a display device according to claim 1,
wherein the cover is at least temporarily moved by the drive unit in the direction parallel to the light exit side, so that depending on the position of the cover relative to the mask layer, light is emitted from the display device at different locations and/or in different directions and/or with mutually different optical properties.

17. A display device with
at least one light-emitting semiconductor chip having a light exit side,
at least one mask layer which is arranged downstream of the semiconductor chip and which comprises a plurality of openings in which the semiconductor chip is free of the mask layer,
at least one movable cover made of an opaque material and having a plurality of penetrations for adjusting a radiation characteristic of the semiconductor chip so that the penetrations are at least temporarily associated with the openings, and
at least one drive unit for moving the cover in a direction parallel to the light exit side,
wherein
the mask layer is of an opaque reflective material,
the mask layer is immobile and stationary relative to the semiconductor chip and comprises constant optical properties, and
a thickness of the mask layer is at least as large as an average diameter of the openings, and
a thickness of the cover is at least half as large as a mean diameter of the penetrations.
